(19) United States
(12) Patent Application Publication
(10) Pub. No.: US 2026/0143990 A1
(43) Pub. Date: May 21, 2026

(54) SUBSTRATE PROCESSING APPARATUS

(71) Applicant: Tokyo Electron Limited, Tokyo (JP)

(72) Inventors: Takafumi KINOSHITA, Koshi City (JP); Tomoyuki HASHIMOTO, Koshi City (JP); Yuki ITO, Koshi City (JP); Kazuhiro AIURA, Koshi City (JP); Yoshifumi AMANO, Nirasaki City (JP); Yuki SUEMATSU, Koshi City (JP); Kenta HAMAHARA, Koshi City (JP)

(73) Assignee: Tokyo Electron Limited, Tokyo (JP)

(21) Appl. No.: 19/390,952

(22) Filed: Nov. 17, 2025

(30) Foreign Application Priority Data
Nov. 18, 2024 (JP) 2024-200512

(51) Int. Cl. H01L 21/67

(52) U.S. Cl. CPC H10P 72/0411

(57) ABSTRACT

A substrate processing apparatus includes a support supporting a substrate; an annular member surrounding the support from an outside thereof; a cover member disposed around the annular member, the cover member having an annular shape; a rotator rotating the support; and a second supply. The cover member includes a rectifying protrusion, extending in a vertical direction to face a periphery of the substrate supported by the support, positioned at an inner side than the annular member when viewed from the vertical direction; a horizontal portion extending in a horizontal direction to be positioned above the annular member; and a sidewall portion extending in the vertical direction to surround an outer peripheral surface of the annular member. The second supply supplies a cleaning liquid to the rectifying protrusion or the annular member.

### CROSS-REFERENCE TO RELATED APPLICATION

This application claims the benefit of Japanese Patent Application No. 2024-200512 filed on Nov. 18, 2024, the entire disclosures of which are incorporated herein by reference.

### TECHNICAL FIELD

The various aspects and embodiments described herein pertain generally to a substrate processing apparatus.

### BACKGROUND

Patent Document 1 discloses a liquid processing apparatus processes a rear surface of a substrate with a processing liquid (e.g., a chemical liquid, a rinse liquid, or the like). The apparatus includes a support that supports the substrate, a rotator that rotates the substrate supported by the support, a supply that supplies a cleaning liquid to the rear surface of the substrate supported by the support, and a cup disposed to surround the substrate supported by the support. When the cleaning liquid is supplied from the supply to the rear surface of the substrate being rotated, the cleaning liquid flows from the center of the rear surface of the substrate toward a periphery thereof due to a centrifugal force. As a result, the rear surface of the substrate is processed. The cleaning liquid shaken off from the substrate scatters toward the cup, is collected in the cup, and then drained to the outside of the liquid processing apparatus.

Patent Document 1: Japanese Patent Laid-open Publication No. 2010-021279

### SUMMARY

In an exemplary embodiment, a substrate processing apparatus includes a support supporting a substrate; an annular member surrounding the support from an outside thereof; a cover member disposed around the annular member, the cover member having an annular shape; a rotator configured to rotate the support; a first supply configured to supply a processing liquid toward a rear surface of the substrate supported by the support; and a second supply. The cover member includes a rectifying protrusion, extending in a vertical direction to face a periphery of the substrate supported by the support, positioned at an inner side than the annular member when viewed from the vertical direction; a horizontal portion extending in a horizontal direction to be positioned above the annular member; and a sidewall portion extending in the vertical direction to surround an outer peripheral surface of the annular member. The second supply is configured to supply a cleaning liquid to the rectifying protrusion or the annular member.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view illustrating an example (first example) of a substrate cleaning apparatus;

FIG. 2 is a schematic cross sectional view partially illustrating a rectifier and its vicinity in the substrate cleaning apparatus of FIG. 1;

FIG. 3 is a block diagram illustrating an example of main components of the substrate cleaning apparatus of FIG. 1;

FIG. 4 is a schematic diagram illustrating an example of a hardware configuration of a controller;

FIG. 5 is a diagram illustrating an example of a cleaning processing for a substrate in the substrate cleaning apparatus of FIG. 1;

FIG. 6 is a diagram illustrating an example of a cleaning processing for the rectifier in the substrate cleaning apparatus in FIG. 1;

FIG. 7 is a diagram illustrating a process following that of FIG. 6;

FIG. 8 is a diagram illustrating a process following that of FIG. 7;

FIG. 9 is a diagram illustrating a process following that of FIG. 8;

FIG. 10 is a diagram illustrating variations in flows rates of respective liquids, a flow rate of an inert gas, and a rotational speed of a rotator over time in the example of the cleaning processing for the rectifier;

FIG. 11 is a schematic cross sectional view illustrating a rectifier and its vicinity in another example (second example) of the substrate cleaning apparatus;

FIG. 12 is a schematic cross sectional view illustrating a rectifier and its vicinity in yet another example (third example) of the substrate cleaning apparatus;

FIG. 13 is a diagram illustrating a cleaning processing for the rectifier in the substrate cleaning apparatus of FIG. 12;

FIG. 14 is a diagram illustrating a process following that of FIG. 13; and

FIG. 15 is a schematic cross sectional view partially illustrating a rectifier and its vicinity in still another example (fourth example) of the substrate cleaning apparatus.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In the following description, same parts or parts with same functions will be assigned same reference numerals, and redundant descriptions thereof will be omitted. Further, in the present specification, the terms “upper,” “lower,” “right,” and “left” in the drawings are based on the direction of reference numerals in the drawings.

### [Configuration of Substrate Cleaning Apparatus]

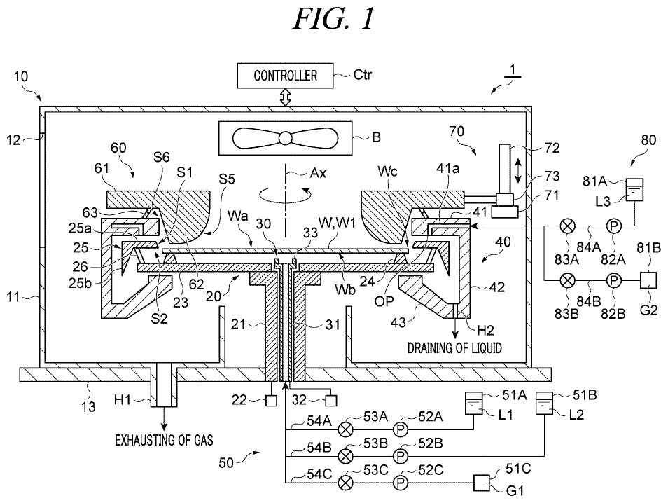

First, an example configuration of a substrate cleaning apparatus 1 (substrate processing apparatus) will be explained with reference to FIG. 1 to FIG. 4. The substrate cleaning apparatus 1 is configured to clean a rear surface Wb of a substrate W with a cleaning liquid (processing liquid). The substrate cleaning apparatus 1 is also configured to clean a rectifier 60 (to be described later) and its vicinity by using a cleaning substrate W1.

The substrate W may be, by way of example, a semiconductor substrate (silicon wafer). The substrate W may have a diameter of, e.g., about 200 mm to about 450 mm. The substrate W may be of a circular plate shape, or a non-circular plate shape such as a polygon. The substrate W may have a partially cut-out portion. The cut-out portion may be, for example, a notch (a U-shaped or V-shaped groove) or a linear portion extending in a straight line shape (so-called orientation flat). The cleaning substrate W1 has a shape corresponding to the substrate W. For example, the cleaning substrate W1 may have approximately the same shape as the substrate W.

As illustrated in FIG. 1, the substrate cleaning apparatus 1 includes a housing 10, a rotator 20, an elevating device 30, a cup member 40 (cover member), a supply 50 (first supply), a rectifier 60 (cover member), an elevating device 70, a supply 80 (second or third supply), a blower B, and a controller Ctr (control device).

The housing 10 accommodates therein the rotator 20, the elevating device 30, the cup member 40, the rectifier 60, the elevating device 70, and the blower B. A carry-in/out opening 12 is formed in a sidewall 11 of the housing 10. The substrate W and the cleaning substrate W1 are carried into and out of the housing 10 through the carry-in/out opening 12 by a non-illustrated transfer mechanism (e.g., a robot arm or the like). An exhaust pipe H1 extending downwards is provided in a bottom wall 13 of the housing 10. The exhaust pipe H1 is connected to a non-illustrated suction pump and functions as an exhaust passage for exhausting a gas from the cup member 40 to the outside of the housing 10.

The rotator 20 includes a rotation shaft 21, a driving mechanism 22, a support plate 23 (support), multiple support pins 24 (support), and an annular member 25. The rotation shaft 21 is a hollow tubular member that extends vertically. The rotation shaft 21 is fixed to the bottom wall 13 of the housing 10 so as to be rotatable around a central axis Ax.

The driving mechanism 22 is connected to the rotation shaft 21. The driving mechanism 22 is operated in response to an operation signal from the controller Ctr, and is configured to rotate the rotation shaft 21. The driving mechanism 22 may be a power source such as an electric motor.

The support plate 23 is, for example, a flat plate having a circular ring shape, and extends horizontally. That is, a through hole is formed in a central portion of the support plate 23. An inner periphery of the support plate 23 is connected to a leading end of the rotation shaft 21. Therefore, the support plate 23 is configured to be rotated around the central axis Ax of the rotation shaft 21 in conjunction with the rotation of the rotation shaft 21.

The multiple support pins 24 are provided on the support plate 23 so as to be protruded upwards from a top surface of the support plate 23. The multiple support pins 24 are configured to support the substrate W or the cleaning substrate W1 substantially horizontally by having their leading ends come into contact with the rear surface Wb of the substrate W or the cleaning substrate W1. The multiple support pins 24 may have, for example, a cylindrical shape or a frustum shape. The multiple support pins 24 may be arranged at an approximately equal interval therebetween near an outer periphery of the support plate 23 so as to form a circle as a whole when viewed from above. For example, if there are 12 multiple support pins 24, these support pins 24 may be arranged at an interval of approximately 30°.

The annular member 25 has a circular ring shape and is disposed to surround the support plate 23 and the multiple support pins 24 from the outside. That is, the annular member 25 is configured to surround the substrate W or the cleaning substrate W1 supported by the multiple support pins 24 from the outside. The annular member 25 is connected to the outer periphery of the support plate 23 by a plurality of connection members 26. Therefore, the annular member 25 is configured to be rotated around the central axis Ax of the rotation shaft 21 in conjunction with the rotation of the rotation shaft 21.

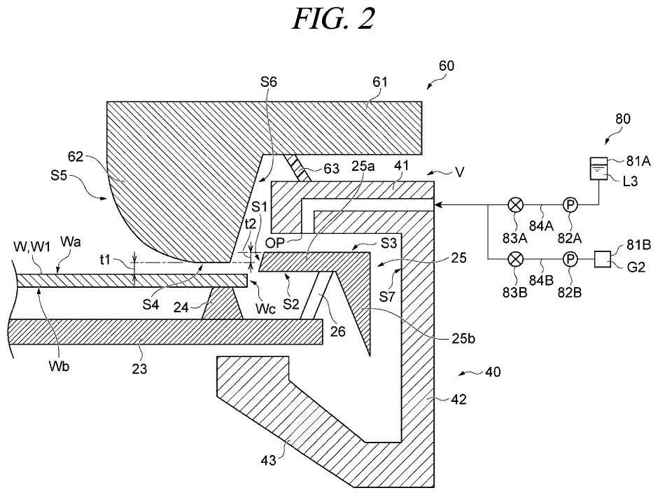

As shown in FIG. 1 and FIG. 2, the annular member 25 may include an upper wall portion 25a and a sidewall portion 25b. The upper wall portion 25a is, for example, a circular ring-shaped plate that extends horizontally. As illustrated in FIG. 2, an inner peripheral surface of the upper wall portion 25a is formed as an inclined surface S1 that is inclined with respect to the horizontal direction. The inclined surface S1 slopes downwards toward the center of the annular member 25 in a radial direction of the annular member 25. In other words, the inclined surface S1 slopes downwards toward an inner side in the radial direction. The height position of a bottom surface S2 of the upper wall portion 25a may be higher than, equal to, or lower than the height position of the top surface Wa of the substrate W or the cleaning substrate W1 supported by the multiple support pins 24.

Due to the presence of the inclined surface S1 and the bottom surface S2, an inner periphery of the upper wall portion 25a may be tapered toward the inner side in the radial direction. Each of the inclined surface S1 and the bottom surface S2 may be a flat surface or a non-flat (e.g., curved) surface. To enhance the fluidity of cleaning liquids L1 and L2 (to be described later), the surface of the annular member 25, including the inclined surface S1 and the bottom surface S2, may include multiple irregularities by, for example, a dimple processing and/or an embossing processing, or may include grooves or protrusions extending along the radial direction. Alternatively, in order to enhance the fluidity of the cleaning liquid L1 and L2, the surface of the annular member 25, including the inclined surface S1 and the bottom surface S2, may be surface-treated or may have a coating film formed thereon.

The sidewall portion 25b may be of a cylindrical shape, for example. An upper end of the sidewall portion 25b may be integrally connected to an outer periphery of the upper wall portion 25a. The sidewall portion 25b may be tapered downwards.

The elevating device 30 includes, as illustrated in FIG. 1, a shaft member 31, a driving mechanism 32, and multiple support pins 33. The shaft member 31 is a hollow tubular member extending vertically. The shaft member 31 is configured to be movable up and down (i.e., along a vertical axis). The shaft member 31 is inserted through the inside of the rotation shaft 21.

The driving mechanism 32 is connected to the shaft member 31. The driving mechanism 32 is operated in response to an operation signal from the controller Ctr, and is configured to move the shaft member 31 up and down. The driving mechanism 32 moves the shaft member 31 up and down, so that the shaft member 31 may be moved up and down between a raised position (not shown) where the multiple support pins 33 are positioned above the multiple support pins 24 and a lowered position (see FIG. 1) where the multiple support pins 33 are positioned below the multiple support pins 24. The driving mechanism 32 may be a power source such as a linear actuator.

The multiple support pins 33 are provided in the shaft member 31 so as to protrude upwards from an upper end of the shaft member 31. The multiple support pins 33 are configured to support the substrate W or the cleaning substrate W1 by having their leading ends to come into contact with the rear surface Wb of the substrate W or the cleaning substrate W1. The multiple support pins 33 may have, for example, a cylindrical shape or a frustum shape. The multiple support pins 33 may be arranged at an approximately equal interval therebetween so as to form a circle as a whole when viewed from above.

The cup member 40 has a circular ring shape as a whole, and is disposed to surround the annular member 25 and the support plate 23 from the outside. The cup member 40 functions as a liquid collection vessel that receives the cleaning liquids L1 and L2 shaken off from the substrate W after being supplied to the rear surface Wb of the substrate W or the cleaning substrate W1.

As illustrated in FIG. 1 and FIG. 2, the cup member 40 may include an upper wall portion 41 (horizontal portion), a sidewall portion 42, and a bottom wall portion 43. The upper wall portion 41 is a plate-shaped body having a circular ring shape and extends horizontally. The upper wall portion 41 is located above the annular member 25 and overlaps with the whole or most of the annular member 25 when viewed from above. The upper wall portion 41 may or may not overlap with the inclined surface S1 when viewed from above. For example, an inner peripheral surface of the upper wall portion 41 may be located at an outer side than the inclined surface S1 in the radial direction. In other words, the inclined surface S1 may be located closer to the center of the annular member 25 than the inner peripheral surface of the upper wall portion 41. When viewed from above, the upper wall portion 41 does not overlap with the substrate W supported by the support pins 24.

A flow path 41a is formed inside the upper wall portion 41. The flow path 41a branches into multiple branch paths at an intermediate portion thereof. Each of the multiple branch paths of the flow path 41a is connected to multiple discharge openings OP formed in a bottom surface of the upper wall portion 41. These multiple discharge openings OP are open toward a top surface S3 of the upper wall portion 25a. That is, a cleaning liquid L3 (to be described later) and an inert gas G2 (to be described later) flowing through the flow path 41a are supplied to the top surface S3 of the upper wall portion 25a. The multiple discharge openings OP may be arranged at an approximately equal interval therebetween so as to form a circle as a whole when viewed from above.

The sidewall portion 42 extends vertically to surround an outer peripheral surface of the annular member 25 (sidewall portion 25b). The sidewall portion 42 may be of, for example, a cylindrical shape. An upper end of the sidewall portion 42 may be integrated with an outer periphery of the upper wall portion 41. A lower end of the sidewall portion 42 may be integrated with an outer periphery of the bottom wall portion 43. The bottom wall portion 43 may be inclined upwards as it goes inwards in the radial direction. A through hole H2 is provided in a bottom of the bottom wall portion 43. The through hole H2 functions as a drain path for draining the cleaning liquids L1 to L3 collected in the cup member 40 to the outside of the housing 10.

As illustrated in FIG. 1, the supply 50 is configured to supply the cleaning liquids L1 and L2 (processing liquids) and an inert gas G1 to the rear surface Wb of the substrate W through the inside of the shaft member 31. That is, the shaft member 31 functions as a nozzle configured to supply the cleaning liquids L1 and L2 and the inert gas G1 to the rear surface Wb of the substrate W. The supply 50 includes liquid sources 51A and 51B, a gas source 51C, pumps 52A to 52C, valves 53A to 53C, and pipelines 54A to 54C.

The liquid source 51A functions as a source for the cleaning liquid L1. The cleaning liquid L1 may be, for example, a cleaning liquid for removing an unnecessary film, such as SiN, adhering to the rear surface Wb of the substrate W. This cleaning liquid may include, by way of example, a DHF solution (dilute hydrofluoric acid), a SC-1 solution (a mixture of ammonia, hydrogen peroxide, and pure water), or hydrogen peroxide solution. The pump 52A operates in response to a signal from the controller Ctr to draw in the cleaning liquid L1 from the liquid source 51A and deliver it to the shaft member 31 via the valve 53A and the pipeline 54A. The valve 53A operates in response to a signal from controller Ctr, and is configured to open and close the pipeline 54A upstream and downstream of the valve 53A. The pipeline 54A connects, in sequence from the upstream side, the liquid source 51A, the pump 52A, and the valve 53A.

The liquid source 51B serves as a source of the cleaning liquid L2. The cleaning liquid L2 may be, by way of example, a rinse liquid for washing away a foreign substance (e.g., particles, chemical liquid residue, etc.). The rinse liquid may include, for example, pure water (i.e., deionized water (DIW)). The pump 52B operates in response to an operation signal from the controller Ctr to draw in the cleaning liquid L2 from the liquid source 51B and deliver it to the shaft member 31 via the valve 53B and the pipelines 54A and 54B. The valve 53B operates in response to an operation signal from the controller Ctr to open and close the pipeline 54B upstream and downstream of the valve 53B. The pipeline 54B connects, in sequence from the upstream side, the liquid source 51B, the pump 52B, and the valve 53B. A downstream end of the pipeline 54B is connected to the pipeline 54A between the valve 53A and the shaft member 31.

The gas source 51C functions as a source of inert gas G1. The inert gas G1 may be, by way of non-limiting example, a nitrogen gas. The pump 52C operates in response to an operation signal from the controller Ctr to draw in the inert gas G1 from the gas source 51C and deliver it to the shaft member 31 via the valve 53C and the pipelines 54A to 54C. The valve 53C operates in response to an operation signal from the controller Ctr to open and close the pipeline 54C upstream and downstream of the valve 53C. The pipeline 54C connects, in sequence from the upstream side, the gas source 51C, the pump 52C, and the valve 53C. A downstream end of the pipeline 54C is connected to the pipeline 54B downstream of the valve 53B.

The rectifier 60 is disposed above the cup member 40. The rectifier 60 is physically separated from the cup member 40. The rectifier 60 includes a base portion 61 (horizontal portion), a rectifying protrusion 62, and a seal member 63.

The base portion 61 is a plate-shaped body having, for example, a circular ring shape, and extends horizontally. The base portion 61 is located above the annular member 25. When viewed from above, an outer periphery of the base portion 61 overlaps the whole or most of the annular member 25. Meanwhile, when viewed from above, an inner periphery of the base portion 61 does not overlap the upper wall portion 41, but overlaps a periphery Wc of the substrate W or the cleaning substrate W1, which is supported by the multiple support pins 24.

The rectifying protrusion 62 is configured to protrude downwards from a bottom surface of the inner periphery of the base portion 61. That is, the rectifying protrusion 62 extends vertically. Therefore, when viewed from above, the rectifying protrusion 62 overlaps (directly faces) the periphery Wc of the substrate W or the cleaning substrate W1 supported by the multiple support pins 24, and also overlaps the multiple support pins 24. When viewed from above, the rectifying protrusion 62 is located at an inner side than the annular member 25.

As illustrated in FIG. 2, a bottom surface S4 of the rectifying protrusion 62 may be located above the top surface Wa of the substrate W or the cleaning substrate W1 supported by the multiple support pins 24 and below the top surface S3 of the upper wall portion 25a of the annular member 25. In other words, the height position of the bottom surface S4 of the rectifying protrusion 62 may overlap the inclined surface S1 when viewed from the horizontal direction.

A linear distance t1 between the bottom surface S4 of the rectifying protrusion 62 and the top surface Wa of the substrate W or the cleaning substrate W1 supported by the multiple support pins 24 may be, for example, about 1 mm to about 2 mm. A linear distance t2 between the bottom surface S4 of the rectifying protrusion 62 and the top surface S3 of the upper wall portion 25a of the annular member 25 may be, for example, about 0.5 mm to about 2.5 mm, or about 1.6 mm to about 1.8 mm.

An inner peripheral surface S5 of the rectifying protrusion 62 is inclined outwards in the radial direction as it goes from top to bottom. The inner peripheral surface S5 of the rectifying protrusion 62 may be a horn-shaped curved surface, as illustrated in FIG. 2. The curved surface may protrude toward the center of the rectifier 60. Although not illustrated, the inner peripheral surface S5 of the rectifying protrusion 62 may be a truncated cone-shaped surface. That is, when the cross section of the rectifying protrusion 62 is viewed from the horizontal direction, the inner peripheral surface S5 of the rectifying protrusion 62 may extend flat.

An outer peripheral surface S6 of the rectifying protrusion 62 may be inclined inwards in the radial direction as it goes from top to bottom. As illustrated in FIG. 2, when the cross section of the rectifying protrusion 62 is viewed from the horizontal direction, the outer peripheral surface S6 of the rectifying protrusion 62 may extend flat. The outer peripheral surface S6 near a lower end of the rectifying protrusion 62 may face the inclined surface S1 of the upper wall portion 25a of the annular member 25 in the horizontal direction when the rectifier 60 is placed at a processing position (to be described below) (see FIG. 2). By way of example, the outer peripheral surface S6 near the lower end of the rectifying protrusion 62 may extend substantially parallel to the inclined surface S1 of the upper wall portion 25a of the annular member 25 when the rectifier 60 is located at the processing position.

The seal member 63 is a cylindrical body having an annular shape. As illustrated in FIG. 2, the seal member 63 may have a cylindrical truncated cone shape with its diameter increasing outwards in the radial direction as it goes from top to bottom. As shown in FIG. 2, the seal member 63 may be provided on a bottom surface of the outer periphery of the base portion 61 so as to be protruded downwards from this bottom surface. Although not shown, the seal member 63 may be provided on a top surface of the upper wall portion 41 so as to be protruded upwards from the top surface.

When the rectifier 60 is located at the processing position (see FIG. 2), the seal member 63 is held between the bottom surface of the outer periphery of the base portion 61 and the top surface of the upper wall portion 41. This allows the seal member 63 to seal a space V (see FIG. 2) between the bottom surface of the outer periphery of the base portion 61 and the top surface of the upper wall portion 41. The seal member 63 may be made of a flexible material (for example, fluoroelastomer, silicone rubber, ethylene propylene rubber, etc.). In this case, when the seal member 63 seals the space V, it deforms and comes into firm contact with the base portion 61 and the upper wall portion 41, which increases the airtightness (sealability) between the base portion 61 and the upper wall portion 41.

As shown in FIG. 1, the elevating device 70 is configured to move the rectifier 60 up and down based on an instruction from the controller Ctr. Specifically, the elevating device 70 is configured to move the rectifier 60 up and down between a raised position where the substrate W or the cleaning substrate W1 is allowed to be carried with respect to the multiple support pins 24 and the processing position (see FIG. 1 and FIG. 2) where the rectifier 60 is positioned near the upper wall portion 41 of the cup member 40 to process the substrate W or the cleaning substrate W1.

The elevating device 70 may be, by way of example, a linear cylinder. The elevating device 70 may include a base member 71 (stop member), a rod 72, and a slider 73 (stop member). The rod 72 extends linearly upwards from the base member 71. The slider 73 is connected to the rectifier 60 and is configured to be moved up and down along the extension direction (vertical direction) of the rod 72 based on an instruction from the controller Ctr. When the slider 73 descends to a lower end of the rod 72, it comes into contact with the base member 71 and stops. Therefore, the base member 71 and the slider 73 function to restrict the rectifier 60 from moving to a position below the processing position.

The supply 80 is configured to supply the cleaning liquid L3 and the inert gas G2 to the top surface S3 of the annular member 25 (upper wall portion 25a) through the flow path 41a formed inside the upper wall portion 41. The supply 80 includes a liquid source 81A, a gas source 81B, pumps 82A and 82B, valves 83A and 83B, and pipelines 84A and 84B.

The liquid source 81A serves as a source of the cleaning liquid L3. The cleaning liquid L3 may be the same chemical liquid for cleaning as the cleaning liquid L1, or may be the same rinse liquid as the cleaning liquid L2. The pump 82A is operated in response to an operation signal from the controller Ctr and is configured to draw in the cleaning liquid L3 from the liquid source 81A and send it to the flow path 41a via the valve 83A and the pipeline 84A. The valve 83A is operated in response to an operation signal from the controller Ctr and is configured to open and close the pipeline 84A upstream and downstream of the valve 83A. The pipeline 84A connects the liquid source 81A, the pump 82A, and the valve 83A in sequence from the upstream to downstream.

The gas source 81b functions as a source of the inert gas G2. The inert gas G2 may be, for example, a nitrogen gas, the same as the inert gas G1. The pump 82B is operated in response to an operation signal from the controller Ctr to draw in the inert gas G2 from the gas source 81B and deliver it to the flow path 41a via the valve 83B and the pipelines 84A and 84B. The valve 83B is operated in response to an operation signal from the controller Ctr to open and close the pipeline 84B upstream and downstream of the valve 83B. The pipeline 84B connects the gas source 81B, the pump 82B, and the valve 83B in sequence from the upstream side. A downstream end of the pipeline 84B is connected to the pipeline 84A downstream of the valve 83A.

In the housing 10, the blower B is located above the rotator 20, the elevating device 30, the cup member 40, and the rectifier 60. The blower B is operated in response to a signal from the controller Ctr and is configured to create a downward flow heading toward the top surface Wa of the substrate W through an inner space of the rectifier 60.

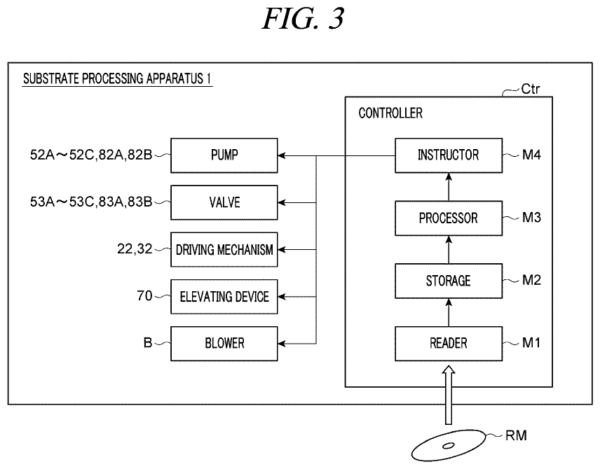

As shown in FIG. 3, the controller Ctr includes, as functional modules, a reader M1, a storage M2, a processor M3, and an instructor M4. These functional modules are nothing more than divisions of functions of the controller Ctr for convenience's sake, and it does not necessarily imply that the hardware constituting the controller Ctr is divided into these modules. Each functional module is not limited to being implemented by execution of a program but may be implemented by a dedicated electric circuit (for example, a logic circuit) or an ASIC (Application Specific Integrated Circuit) as an integration of these electric circuits. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The reader M1 is configured to read a program from a computer-readable recording medium RM. The recording medium RM stores thereon a program for operating the individual components of the substrate cleaning apparatus 1 (for example, the driving mechanisms 22 and 32, the pumps 52A to 52C, 82A, and 82B, the valves 53A to 53C, 83A, and 83B, the elevating device 70, the blower B, and so forth). The recording medium RM may be, by way of example, but not limitation, a semiconductor memory, an optical recording disk, a magnetic recording disk, a magneto-optical recording disk, or the like. The recording medium RM may be embedded in the substrate cleaning apparatus 1, or may be separate from the substrate cleaning apparatus 1.

The storage M2 may be configured to store therein various types of data. The storage M2 may store therein, for example, the program read out from the recording medium RM in the reader M1, setting data input from an operator through an external input device (not shown), and so forth.

The processor M3 is configured to process various types of data. By way of example, the processor M3 may generate operation signals for operating the individual components of the substrate cleaning apparatus 1 based on the various types of data stored in the storage M2.

The instructor M4 is configured to transmit the operation signals generated by the processor M3 to the individual components of the substrate cleaning apparatus 1.

The instructor M4 may perform a first support processing of supporting the substrate W with the multiple support pins 33 in a state that the rectifier 60 is raised to the raised position by the elevating device 70 and the shaft member 31 is raised to the raised position by the driving mechanism 32. After the first support processing, the instructor M4 may perform a first lowering processing of lowering the shaft member 31 to the lowered position by the driving mechanism 32 and lowering the rectifier 60 to the processing position by the elevating device 70 in a state that the substrate W is supported by the multiple support pins 33. At this time, the substrate W is placed on the multiple support pins 24. After the first lowering processing, the instructor M4 may perform a first cleaning processing of controlling the supply 50 to supply the cleaning liquids L1 and L2 from the shaft member 31 toward the rear surface Wb of the substrate W supported by the multiple support pins 24, while rotating the substrate W by using the rotator 20.

The instructor M4 may perform a second support processing of supporting the cleaning substrate W1 with the multiple support pins 33 in a state that the rectifier 60 is raised to the raised position by the elevating device 70 and the shaft member 31 is raised to the raised position by the driving mechanism 32. After the second support processing, the instructor M4 may perform a second lowering processing of lowering the shaft member 31 to the lowered position by the driving mechanism 32 and lowering the rectifier 60 to the processing position by the elevating device 70 in a state that the cleaning substrate W1 is supported by the multiple support pins 33. At this time, the cleaning substrate W1 is placed on the multiple support pins 24.

After the second lowering processing, the instructor M4 may perform a second cleaning processing (third processing) of controlling the driving mechanism 22 and the supply 80 to supply the cleaning liquid L3 from the multiple discharge openings OP to the top surface S3 of the annular member 25 while rotating the support pins 24 and annular member 25. The second cleaning processing may include supplying the cleaning liquid L3 from the multiple discharge openings OP to the top surface S3 of the annular member 25 while rotating the support pins 24 and the annular member 25 at a first rotational speed (first processing). The second cleaning processing may further include supplying the cleaning liquid L3 from the multiple discharge openings OP to the top surface S3 of the annular member 25 while rotating the support pins 24 and the annular member 25 at a second rotational speed (second processing) that is lower than the first rotational speed.

After the second cleaning processing, the instructor M4 may perform a drying processing (fourth processing) of controlling the supply 80 to supply the inert gas G2 to the annular member 25. The drying processing may include supplying the inert gas G2 from the multiple discharge openings OP to the top surface S3 of the annular member 25 while rotating the support pins 24 and annular member 25.

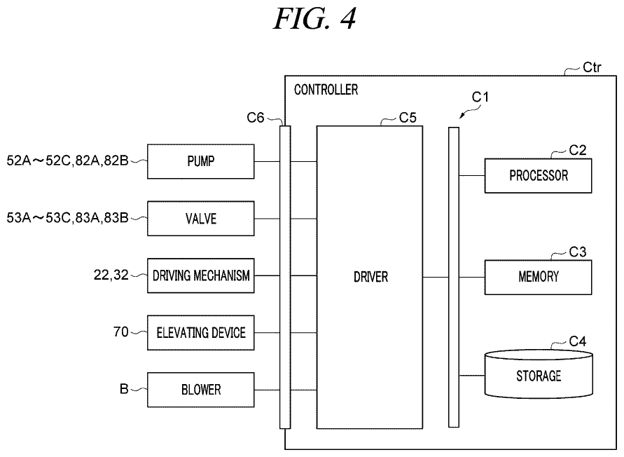

The hardware of the controller Ctr may be composed of, by way of example, one or more control computers. The controller Ctr may include, for example, a circuit C1 shown in FIG. 4 as a hardware configuration. The circuit C1 may be composed of electric circuit elements (circuitry). The circuit C1 may include, for example, a processor C2, a memory C3 (storage), a storage C4 (storage), a driver C5, and an input/output port C6. The processor C2 constitutes the aforementioned individual functional modules by executing the program in cooperation with at least one of the memory C3 or the storage C4 and performing an input/output of signals via the input/output port C6. The memory C3 and the storage C4 serve as the storage M2. The driver C5 is a circuit configured to drive the individual components of the substrate cleaning apparatus 1. The input/output port C6 performs an input/output of signals between the driver C5 and the individual components of the substrate cleaning apparatus 1.

The substrate cleaning apparatus 1 may be equipped with the one controller Ctr or a controller group (control module) composed of a multiple number of controllers Ctr. In the latter case, each of the aforementioned functional modules may be implemented by a single controller Ctr or a combination of two or more controllers Ctr. If the controller Ctr is composed of a plurality of computers (circuits C1), each of the aforementioned functional modules may be implemented by a single computer (circuit C1) or a combination of two or more computers (circuits C1). The controller Ctr may include a plurality of processors C2. In this case, each of the aforementioned functional modules may be implemented by a single processor C2 or a combination of two or more processors C2.

### Cleaning Processing of Substrate

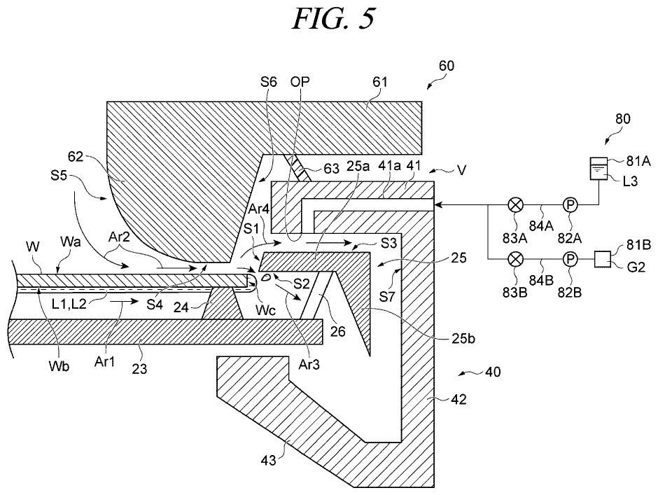

Now, with reference to FIG. 5, a cleaning processing for the substrate W in the substrate cleaning apparatus 1 will be explained.

First, the substrate W is carried into the housing 10 by a non-illustrated transfer mechanism. At this time, the controller Ctr controls the driving mechanism 32 to locate the shaft member 31 at the raised position. Further, the controller Ctr controls the elevating device 70 to locate the rectifier 60 at the raised position. The substrate W carried into the housing 10 through the carry-in/out opening 12 is handed over onto the support pins 33 from the transfer mechanism. As a result, the substrate W is placed on the support pins 33 (elevating device 30) so that its rear surface Wb is in contact with the support pins 33.

Next, the controller Ctr controls the driving mechanism 32 to lower the shaft member 31 to the lowered position. During the lowering of the shaft member 31, the substrate W is handed over from the support pins 33 onto the support pins 24. As a result, the substrate W is placed on the support pins 24 (rotator 20) so that its rear surface Wb is in contact with the support pins 24.

Thereafter, the controller Ctr controls the elevating device 70 to lower the rectifier 60 to the processing position. This allows the seal member 63 to be held between the bottom surface of the outer periphery of the base portion 61 and the top surface of the upper wall portion 41, hermetically sealing the space V.

Next, the controller Ctr controls the driving mechanism 22 to rotate the rotation shaft 21 at a preset rotational speed. At this time, the support plate 23 and the annular member 25 are rotated via the rotation shaft 21, and the substrate W placed on the support pins 24 is also rotated. The controller Ctr also controls the blower B to create the downward flow heading toward the top surface Wa of the substrate W through the inner space of the rectifier 60.

Thereafter, the controller Ctr controls the supply 50 to supply the cleaning liquids L1 and L2 through the shaft member 31 toward the rear surface Wb of the substrate W being rotated. Accordingly, as illustrated in FIG. 5, the cleaning liquids L1 and L2 flow along the rear surface Wb toward the outer edge of the substrate W due to the centrifugal force, and are then shaken off outwards from the outer edge of the substrate W (see an arrow Ar1 in FIG. 5). As a result, the entire rear surface Wb of the substrate W is cleaned by the cleaning liquids L1 and L2.

Meanwhile, the downward flow formed by the blower B flows along the inner peripheral surface S5 of the rectifying protrusion 62 and flows into a gap between the bottom surface S4 of the rectifying protrusion 62 and the top surface Wa of the substrate W (see an arrow Ar2 in FIG. 5). The flow then branches into a first branch flow (indicated by an arrow Ar3 in FIG. 5) and a second branch flow (indicated by an arrow Ar4 in FIG. 5). The first branch flow flows toward a gap between the inclined surface S1 of the upper wall portion 25a of the annular member 25 and the periphery Wc of the substrate W. The second branch flow flows toward a gap between the inclined surface S1 of the upper wall portion 25a of the annular member 25 and the outer peripheral surface S6 of the rectifying protrusion 62. Therefore, as shown in FIG. 5, the cleaning liquids L1 and L2 shaken off from the substrate W are mainly blocked by the first branch flow, and are suppressed from flowing back to the top surface Wa of the substrate W. Furthermore, even if droplets of the cleaning liquids L1 and L2 shaken off from the substrate W collide with the upper wall portion 25a or the like to splash upwards or become mist, the presence of the rectifying protrusion 62 suppresses the droplets from reaching the center of the substrate W, and the droplets are made to flow between the inclined surface S1 and the outer peripheral surface S6 along with the second branch flow. Meanwhile, the splashing of the droplets of the cleaning liquids L1 and L2 or the scattering of the mist may cause the droplets or the mist to adhere to and accumulate on a circumferential surfaces (e.g., the bottom surface S4, a lower region of the inner peripheral surface S5, and a lower region of the outer peripheral surface S6) of the rectifying protrusion 62, the top surface S3 of the annular member 25 (upper wall portion 25a), the inner peripheral surface S7 of the cup member 40 (sidewall portion 42), and the like. In this case, a foreign substance (e.g., particles, chemical liquid residue, etc.) may be generated on the circumferential surface of the rectifying protrusion 62, the top surface S3 of the annular member 25, the inner peripheral surface S7 of the cup member 40, and the like.

Next, upon the lapse of a preset time, the controller Ctr controls the supply 50 to stop the supply of the cleaning liquids L1 and L2. Then, the controller Ctr controls the driving mechanism 22 to stop the rotation of the rotation shaft 21.

Thereafter, the controller Ctr controls the elevating device 70 to raise the rectifier 60 to the raised position. Then, the controller Ctr controls the driving mechanism 32 to raise the shaft member 31 to the raised position. During the raising of the shaft member 31, the substrate W is also raised while being handed over from the support pins 24 onto the support pins 33. Accordingly, the substrate W is placed on the support pins 33 so that its rear surface Wb is in contact with the support pins 33.

Then, a non-illustrated transfer mechanism receives the substrate W from the support pins 33 and carries out the received substrate W from the housing 10, which ends the cleaning processing for the rear surface Wb of the substrate W.

### Cleaning Processing of Rectifying Protrusion or the Like

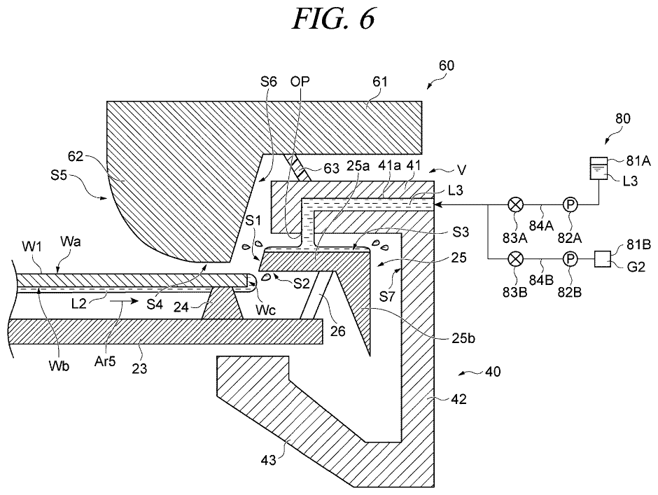

As stated above, due to the cleaning processing of the substrate W, the foreign substance may adhere to the circumferential surface of the rectifying protrusion 62, the top surface S3 of the annular member 25, the inner peripheral surface S7 of the cup member 40, and the like. Referring to FIG. 6 to FIG. 10, a cleaning processing of the rectifying protrusion 62 and the like will be explained.

First, the cleaning substrate W1 is carried into the housing 10 by a non-illustrated transfer mechanism. At this time, the controller Ctr controls the driving mechanism 32 to locate the shaft member 31 at the raised position. The controller Ctr also controls the elevating device 70 to locate the rectifier 60 at the raised position. The cleaning substrate W1, which has been carried into the housing 10 through the carry-in/out opening 12, is handed over from the transfer mechanism onto the support pins 33. As a result, the cleaning substrate W1 is placed on the support pins 33 (elevating device 30) so that its rear surface Wb is in contact with the support pins 33.

Then, the controller Ctr controls the driving mechanism 32 to lower the shaft member 31 to the lowered position. During the lowering of the shaft member 31, the cleaning substrate W1 is handed over from the support pins 33 onto the support pins 24. As a result, the cleaning substrate W1 is placed on the support pins 24 (rotator 20) so that its rear surface Wb is in contact with the support pins 24.

Subsequently, the controller Ctr controls the elevating device 70 to lower the rectifier 60 to the processing position. This allows the seal member 63 to be held between the bottom surface of the outer periphery of the base portion 61 and the top surface of the upper wall portion 41, hermetically sealing the space V.

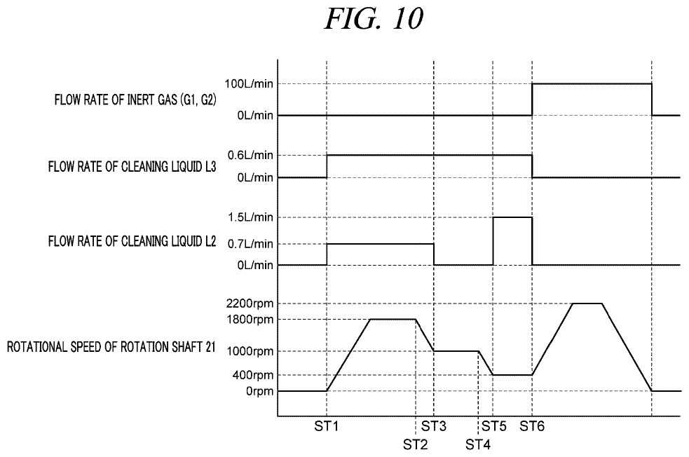

Next, the controller Ctr controls the driving mechanism 22 to start rotation of the rotation shaft 21 (see a process ST1 in FIG. 10). At this time, the support plate 23 and the annular member 25 are rotated via the rotation shaft 21, and the cleaning substrate W1 placed on the support pins 24 is also rotated.

Simultaneously with the start of the rotation of the rotation shaft 21, the controller Ctr controls the supply 50 to supply the cleaning liquid L2 through the shaft member 31 toward the rear surface Wb of the cleaning substrate W1 being rotated (see the process ST1 in FIG. 10). The flow rate of the cleaning liquid L2 at this time may be, by way of example, approximately 0.7 mL/min. Accordingly, as illustrated in FIG. 6, the cleaning liquid L2 flows along the rear surface Wb toward the outer edge of the cleaning substrate W1 due to the centrifugal force, and is then shaken off outwards from the outer edge of the cleaning substrate W1 (see an arrow Ar5 in FIG. 6). As a result, the entire rear surface Wb of the cleaning substrate W1 is cleaned by the cleaning liquid L2.

Furthermore, concurrently with the start of the rotation of the rotation shaft 21, the controller Ctr controls the supply 80 to supply the cleaning liquid L3 through the flow path 41a and the multiple discharge openings OP toward the top surface S3 of the annular member 25 (upper wall portion 25a) being rotated (see the process ST1 in FIG. 10). The flow rate of the cleaning liquid L3 at this time may be, for example, approximately 0.6 mL/min. Accordingly, as illustrated in FIG. 6, the cleaning liquid L3 flows along the entire top surface S3, then scatters inwards from an inner edge of the upper wall portion 25a and also scatters outwards from an outer edge of the upper wall portion 25a. As a result, the entire top surface S3 is cleaned by the cleaning liquid L3.

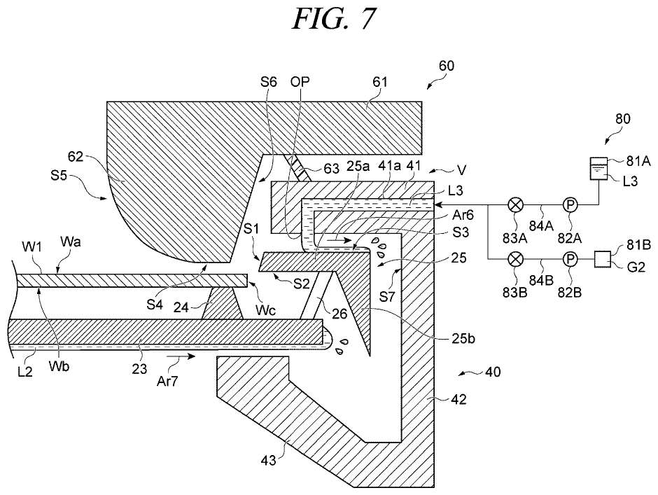

Thereafter, the rotational speed of the rotation shaft 21 is increased until it reaches a preset rotational speed (first rotational speed). The preset rotational speed may be, by way of non-limiting example, about 1800 rpm. In the process of increasing the rotational speed of the rotation shaft 21, as illustrated in FIG. 7, the cleaning liquid L3 discharged onto the top surface S3 of the annular member 25 flows along the top surface S3 toward the outer edge of the upper wall portion 25a due to the centrifugal force, and is then shaken off outwards from the outer edge of the upper wall portion 25a (as indicated by an arrow Ar6 in FIG. 7). The cleaning liquid L3 shaken off outwards from the outer edge of the upper wall portion 25a scatters toward the inner peripheral surface S7 of the cup member 40 (sidewall portion 42) and its vicinity. As a result, the outer peripheral region of the top surface S3 and the inner peripheral surface S7 are cleaned by the cleaning liquid L3.

Thereafter, the controller Ctr controls the driving mechanism 22 to start deceleration of the rotation of the rotation shaft 21 (see a process ST2 in FIG. 10). When the rotational speed of the rotation shaft 21 decreases to a set rotational speed, the controller Ctr controls the supply 50 to stop the supply of the cleaning liquid L2 from the shaft member 31 (see a process ST3 in FIG. 10). The specified rotational speed may be, e.g., about 1000 rpm. In this case, since the rotational speed of the annular member 25 is relatively high even after the deceleration, the cleaning liquid L3 discharged onto the top surface S3 flows toward the outer edge of the upper wall portion 25a due to the centrifugal force (see the arrow Ar6 in FIG. 7).

Further, as illustrated in FIG. 7, after the supply of the cleaning liquid L2 from the shaft member 31 is stopped, the cleaning liquid L2 may be supplied from a non-illustrated nozzle toward a rear surface of the support plate 23. Accordingly, the cleaning liquid L2 flows along the rear surface of the support plate 23 toward the outer edge of the support plate 23 due to the centrifugal force, and is then shaken off outwards from the outer edge of the support plate 23 (see an arrow Ar7 in FIG. 7). As a result, the entire rear surface of the support plate 23 is cleaned by the cleaning liquid L2.

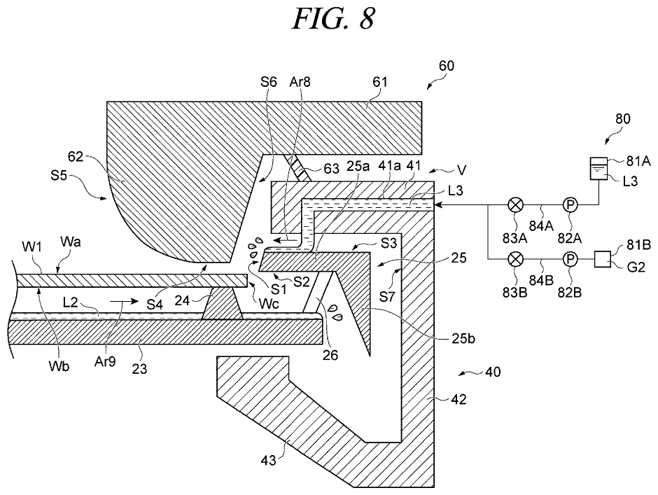

Next, the controller Ctr controls the driving mechanism 22 to start further deceleration of the rotation of the rotation shaft 21 (see a process ST4 in FIG. 10). In this case, due to the deceleration, the cleaning liquid L3 discharged onto the top surface S3 flows along the top surface S3 toward the inner edge of the upper wall portion 25a, and then is shaken off inwards from the inner edge of the upper wall portion 25a (as indicted by an arrow Ar8 in FIG. 8). The cleaning liquid L3 shaken off inwards from the inner edge of the upper wall portion 25a scatters toward the circumferential surface (e.g., the bottom surface S4 and the lower region of the outer peripheral surface S6) of the rectifying protrusion 62 and the vicinity thereof. As a result, primarily, the bottom surface S4 and the lower region of the outer peripheral surface S6 are cleaned by the cleaning liquid L3.

When the rotational speed of the rotation shaft 21 decreases to a prespecified rotational speed (second rotational speed), the controller Ctr controls the supply 50 to supply the cleaning liquid L2 through the shaft member 31 toward the rear surface Wb of the cleaning substrate W1 being rotated (see a process ST5 in FIG. 10). The prespecified rotational speed may be, for example, about 400 rpm. The flow rate of the cleaning liquid L2 may be, by way of example, about 1.5 mL/min. In this case, since the rotational speed of the cleaning substrate W1 is relatively low, the cleaning liquid L2 supplied toward the rear surface Wb of the cleaning substrate W1 flows on the front surface of the support plate 23, as illustrated in FIG. 8. That is, the cleaning liquid L2 flows along the front surface of the support plate 23 toward the outer edge of the support plate 23 due to the centrifugal force, and is then shaken off outwards from the outer edge of the support plate 23 (as indicated by an arrow Ar9 in FIG. 8). As a result, the entire front surface of the support plate 23 is cleaned by the cleaning liquid L2.

Next, upon the lapse of a preset time, the controller Ctr controls the supplies 50 and 80 to stop the supply of the cleaning liquids L2 and L3 (see a process ST6 in FIG. 10). Then, the controller Ctr controls the driving mechanism 22 to increase the rotational speed of the rotation shaft 21.

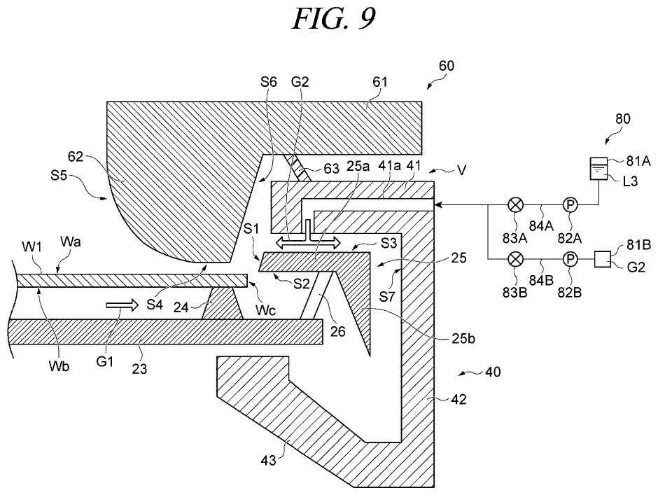

Furthermore, simultaneously with the start of the acceleration of the rotation of the rotation shaft 21, the controller Ctr controls the supply 50 to supply the inert gas G1 through the shaft member 31 toward the rear surface Wb of the cleaning substrate W1 being rotated (see the process ST6 in FIG. 10). The flow rate of the inert gas G1 at this time may be, for example, approximately 100 L/min. Accordingly, as illustrated in FIG. 9, the inert gas G1 flows toward the outer edge of the cleaning substrate W1 through a space between the rear surface Wb of the cleaning substrate W1 and the front surface of the support plate 23. As a result, the space is dried by the inert gas G1.

Also, concurrently with the start of the acceleration of the rotation of the rotation shaft 21, the controller Ctr controls the supply 80 to supply the inert gas G2 through the flow path 41a and the multiple discharge openings OP toward the top surface S3 of the annular member 25 (upper wall portion 25a) being rotated (see the process ST6 in FIG. 10). The flow rate of the inert gas G2 at this time may be, for example, approximately 100 L/min. Accordingly, as illustrated in FIG. 9, the inert gas G2 flows through a space between the upper wall portion 41 and the upper wall portion 25a, a space between the rectifying protrusion 62 and the upper wall portion 25a, and a space between the sidewall portion 25b and the sidewall portion 42. As a result, these spaces are dried by the inert gas G2.

Then, the rotational speed of the rotation shaft 21 is increased until a set rotational speed is obtained. The set rotational speed at this time may be, by way of example, approximately 2200 rpm. Thereafter, the controller Ctr controls the driving mechanism 22 to gradually decelerate the rotation of the rotation shaft 21 until it stops.

Next, the controller Ctr controls the elevating device 70 to raise the rectifier 60 to the raised position. Then, the controller Ctr controls the driving mechanism 32 to raise the shaft member 31 to the raised position. During the raising of the shaft member 31, the cleaning substrate W1 is also raised while being handed over from the support pins 24 onto the support pins 33. Accordingly, the cleaning substrate W1 is placed on the support pins 33 so that the rear surface Wb of the cleaning substrate W1 is in contact with the support pins 33.

Then, a non-illustrated transfer mechanism receives the cleaning substrate W1 from the support pins 33 and carries out the received cleaning substrate W1 from the housing 10, which ends the cleaning processing for the rectifying protrusion 62 and the like.

### Effects

According to the exemplary embodiment described above, the cleaning liquid L3 is supplied to the annular member 25. Since the cleaning liquid L3 that has reached the annular member 25 scatters toward the circumferential surface of the rectifying protrusion 62, the circumferential surface of the rectifying protrusion 62 is cleaned together with the annular member 25. Therefore, even if the foreign substance adheres to the circumferential surface of the rectifying protrusion 62, the foreign substance is washed away by the cleaning liquid L3. This reduces the likelihood of the foreign substance falling from the circumferential surface of the rectifying protrusion 62 toward the substrate W. As a result, it is possible to suppress the adhesion of the foreign substance to the top surface Wa of the periphery Wc of the substrate W. Furthermore, since the circumferential surface of the rectifying protrusion 62 is cleaned by the cleaning liquid L3 supplied from the supply 80, it is not needed to disassemble the substrate cleaning apparatus 1 to clean the rectifying protrusion 62. Therefore, a maintenance work for the substrate cleaning apparatus 1 may be simplified.

In the above exemplary embodiment, the cleaning liquid L3 is supplied to the top surface S3 of the annular member 25 from the multiple discharge openings OP provided in the upper wall portion 41. Therefore, a wide range of the annular member 25 can be cleaned.

According to the above-described exemplary embodiment, the driving mechanism 22 is configured to rotate the support plate 23 and the annular member 25. Thus, due to the rotation of the annular member 25, the cleaning liquid L3 supplied to the annular member 25 is made to scatter around vigorously. This makes it possible to more effectively clean the wide range of the annular member 25.

According to the above-described exemplary embodiment, the cleaning liquid L3 is supplied to the top surface S3 of the annular member 25, which is being rotated at the preset rotational speed (first rotational speed), which is relatively high (first processing). Accordingly, the cleaning liquid L3 supplied to the annular member 25 scatters vigorously outwards in the radial direction. Therefore, the cleaning liquid L3 flows toward the inner peripheral surface S7 of the sidewall portion 42, which is located at the outer side than the annular member 25 in the radial direction. As a result, the inner peripheral surface S7 of the sidewall portion 42 is mainly cleaned. Meanwhile, the cleaning liquid L3 is supplied to the top surface S3 of the annular member 25, which is being rotated at the prespecified rotational speed (second rotational speed), which is relatively low (second processing). Accordingly, the cleaning liquid L3 supplied to the annular member 25 scatters vigorously inwards in the radial direction. Therefore, the cleaning liquid L3 flows toward the outer peripheral surface S6 of the rectifying protrusion 62, which is located at the inner side than the annular member 25 in the radial direction. As a result, the outer peripheral surface S6 of the rectifying protrusion 62 is mainly cleaned. As described above, according to the exemplary embodiment, by controlling the rotational speed of the annular member 25, it is possible to more effectively clean the inner peripheral surface S7 of the sidewall portion 42 and the outer peripheral surface S6 of the rectifying protrusion 62.

According to the above-described exemplary embodiment, the first processing and the second processing are performed with the cleaning substrate W1 supported on the support pins 24. Therefore, the substrate W is not consumed in the cleaning of the rectifying protrusion 62. This makes it possible to clean the rectifying protrusion 62 at low cost.

According to the above-described exemplary embodiment, the rectifying protrusion 62 and the cup member 40 are physically separated from each other. Therefore, by separating the rectifying protrusion 62 from the cup member 40, it is possible to easily place the substrate W and the cleaning substrate W1 on the support pins 24.

According to the above-described exemplary embodiment, the elevating device 70 moves the rectifying protrusion 62 up and down between the raised position and the processing position. Therefore, the carry-in and carry out of the substrate W and the cleaning substrate W1, and the processing of the substrate W and the cleaning substrate W1 can be performed automatically depending on the position of the rectifying protrusion 62.

According to the above-described exemplary embodiment, when the rectifier 60 is located at the processing position, the gap between the rectifier 60 and the cup member 40 is sealed by the seal member 63. Accordingly, this suppresses the gas from flowing into the inner space between the rectifier 60, the cup member 40, and the annular member 25 from the outside through this gap, and also suppresses the gas from being exhausted from the inner space to the outside through this gap. Accordingly, it is easier to maintain the inner space clean, so that the adhesion of the foreign substance to the top surface Wa of the periphery Wc of the substrate W being processed in the inner space can be further suppressed.

According to the above-described exemplary embodiment, when the rectifier 60 is lowered from the raised position to the processing position, the seal member 63 comes into contact with the upper wall portion 41 of the cup member 40 while being deformed to expand outwards in the radial direction. Therefore, even if the positioning of the rectifier 60 relative to the cup member 40 in the horizontal and vertical direction is not precise, the gap between the rectifier 60 and the cup member 40 can still be sealed by the seal member 63. Thus, the gap between the rectifier 60 and the cup member 40 can be sealed with a simple device structure.

According to the above-described exemplary embodiment, after the supply 80 supplies the cleaning liquid L3 to the top surface S3 of the annular member 25, the supply 80 supplies the inert gas G2 to the top surface S3 of the annular member 25. As a result, the annular member 25 and the rectifying protrusion 62 are dried by the inert gas G2. Therefore, it is possible to maintain the annular member 25 and the rectifying protrusion 62 clean.

According to the above-described exemplary embodiment, the inner peripheral surface S5 of the rectifying protrusion 62 of the rectifier 60 slopes outwards in the radial direction as it goes from top to bottom. Therefore, the flow descending from above toward the top surface Wa of the substrate W flows smoothly along the inner peripheral surface S5 to the top surface Wa of the periphery Wc of the substrate W. In addition, since the rectifying protrusion 62 faces the periphery Wc of the substrate W, which is supported by the multiple support pins 24, the gap between the rectifying protrusion 62 and the top surface Wa of the periphery Wc of the substrate W is narrowed. Therefore, the flow smoothly guided to the top surface Wa of the periphery Wc of the substrate W by the inner peripheral surface S5 of the rectifying protrusion 62 flows at a high speed in the narrow passage formed between the bottom surface S4 of the rectifying protrusion 62 and the top surface Wa of the periphery Wc of the substrate W (see the arrow Ar2 in FIG. 5).

In this way, in the above-described exemplary embodiment, since the flow travels at the high speed in the narrow passage, the cleaning liquids L1 and L2 supplied to the rear surface Wb of the substrate W by the supply 50 are blocked by the high-speed flow when they reach the periphery of the substrate W and thus suppressed from flowing back to the top surface Wa of the periphery Wc of the substrate W. As a result, the scattering of the liquid droplets that might be caused when the cleaning liquids L1 and L2 reach the top surface Wa of the periphery Wc of the substrate W is less likely to occur, making it possible to suppress the adhesion of the foreign substance to the top surface Wa of the periphery Wc of the substrate W. Furthermore, the high-speed flow between the rectifying protrusion 62 and the top surface Wa of the periphery Wc of the substrate W does not depend on the rotational speed of the substrate W during the substrate processing. Therefore, during the substrate processing, it is possible to suppress the adhesion of the foreign substance to the top surface Wa of the periphery Wc of the substrate W over the wide range of rotational speeds of the substrate W, from low to high.

According to the above-described exemplary embodiment, the rectifier 60 includes the rectifying protrusion 62 that protrudes from the base portion 61 toward the periphery Wc of the substrate W. Therefore, even if the droplets, the mist, and the like of the cleaning liquids L1 and L2 are scattered near the periphery of the substrate W, most of the scattered substance may adhere to the outer peripheral surface S6 of the rectifying protrusion 62. Therefore, the presence of the rectifying protrusion 62 suppresses the scattered substance from moving toward the center side of the substrate W. As a result, the adhesion of the foreign substance to the top surface Wa of the periphery Wc of the substrate W can be further suppressed.

According to the above-described exemplary embodiment, the rectifying protrusion 62 of the rectifier 60 overlap with the multiple support pins 24 when viewed from above. Therefore, the substrate W is pressed against the multiple support pins 24 due to the high-speed flow that travels through the narrow passage. Therefore, bending of the substrate W is suppressed when the substrate W is processed by the cleaning liquids L1 and L2. As a result, the substrate W can be processed more uniformly.

According to the above-described exemplary embodiment, since the annular member 25 includes the inclined surface S1, the high-speed flow that has flown between the rectifying protrusion 62 and the top surface Wa of the periphery Wc of the substrate W is smoothly guided to the downstream side along the inclined surface S1 (as indicated by the arrow Ar4 in FIG. 5). Therefore, the high-speed flow is less likely to be disturbed between the annular member 25 and the rectifier 60. Accordingly, even if the droplets, the mist, and the like of the cleaning liquids L1 and L2 are scattered near the periphery of the substrate W, the scattered substance flows to the downstream side by being carried on the high-speed flow, which makes it difficult for the scattered substance to adhere to the top surface Wa of the substrate W. As a result, the adhesion of the foreign substance to the top surface Wa of the periphery Wc of the substrate W can be further suppressed.

According to the above-described exemplary embodiment, the base member 71 and the slider 73 restrict the rectifier 60 from moving to the position below the processing position. Therefore, it is possible to locate the rectifier 60 at the predetermined processing position while avoiding the contact between the rectifier 60 and the cup member 40.

According to the above-described exemplary embodiment, the inner peripheral surface S5 of the rectifying protrusion 62 may be the truncated cone-shaped surface or the horn-shaped curved surface. In this case, the flow descending from above toward the top surface Wa of the substrate W flows more smoothly along the inner peripheral surface S5 to the top surface Wa of the periphery Wc of the substrate W.

In the above example, the outer peripheral surface S6 of the rectifying protrusion 62 may be inclined inwards in the radial direction as it goes from top to bottom. In this case, since the outer peripheral surface S6 of the rectifying protrusion 62 extends along the inclined surface S1 of the annular member 25, the width of a downstream passage formed between the outer peripheral surface S6 of the rectifying protrusion 62 and the inclined surface S1 of the annular member 25 is difficult to vary. Therefore, it is possible to secure the narrow passage of a predetermined length for generating the high-speed flow, while suppressing an excessive pressure loss caused by extreme narrowing of the downstream passage.

According to the exemplary embodiment, when the rectifier 60 is placed at the processing position, the outer peripheral surface S6 of the rectifying protrusion 62 may face the inclined surface S1 of the annular member 25 substantially in parallel with the inclined surface S1. In this case, the width of the downstream passage becomes substantially constant. This makes it possible to more effectively secure a preset width of the downstream passage and a specified length of the narrow passage.

According to the above-described exemplary embodiment, the height position of the bottom surface S2 of the annular member 25 may be equal to or higher than the height position of the top surface Wa of the substrate W supported by the multiple support pins 24. In this case, it becomes easier for the high-speed flow generated in the narrow passage to branch into the flow (second branch flow) that travels through the downstream passage formed between the outer peripheral surface S6 of the rectifying protrusion 62 and the inclined surface S1 of the annular member 25 and the flow (first branch flow) that travels through another downstream passage formed between the periphery of the substrate W and the upper wall portion 25a of the annular member 25. Therefore, the likelihood of scattering of the liquid droplets that might occur when the cleaning liquids L1 and L2 flow onto the top surface Wa of the periphery Wc of the substrate W is further reduced, so that the adhesion of the foreign substance to the top surface Wa of the periphery Wc of the substrate W can be further suppressed.

### Modification Examples

The disclosures in the present specification should be considered illustrative in all respects and not restrictive. Various omissions, replacements and modifications may be made without departing from the scope and spirit of the claims.

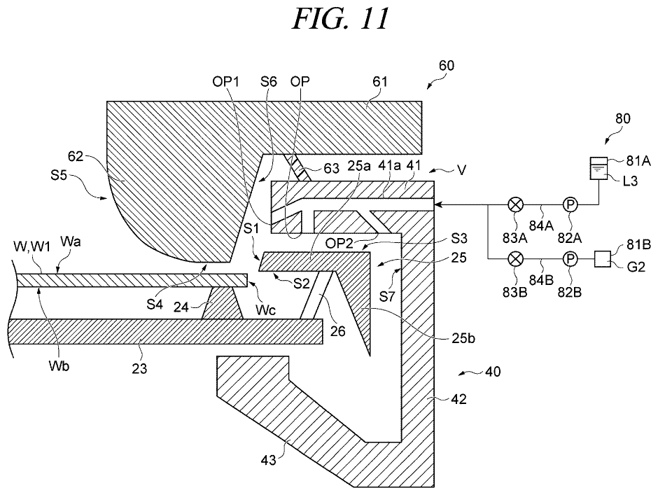

(1) As illustrated in FIG. 11, multiple discharge openings OP1 opened toward the outer peripheral surface S6 of the rectifying protrusion 62 may be formed in the upper wall portion 41. The multiple discharge openings OP1 may be in fluid communication with the flow path 41a. In this case, the cleaning liquid L3 is supplied directly to the outer peripheral surface S6 of the rectifying protrusion 62 through the flow path 41a and the multiple discharge openings OP1. This makes it possible to clean the wide range of the rectifying protrusion 62.

As depicted in FIG. 11, multiple discharge openings OP2 opened toward the inner peripheral surface S7 of the sidewall portion 42 may be formed in the upper wall portion 41. The multiple discharge openings OP2 may be in fluid communication with the flow path 41a. In this case, the cleaning liquid L3 is supplied directly to the inner peripheral surface S7 of the sidewall portion 42 through the flow path 41a and the multiple discharge openings OP2. This makes it possible to clean the wide range of the sidewall portion 42.

The upper wall portion 41 may be provided with at least one group selected from the multiple discharge openings OP, the multiple discharge openings OP1, and the multiple discharge openings OP2. That is, the supply 80 may be configured to supply the cleaning liquid L3 and/or the inert gas G2 to at least one of the top surface S3 of the annular member 25, the outer peripheral surface S6 of the rectifying protrusion 62, and the inner peripheral surface S7 of the sidewall portion 42.

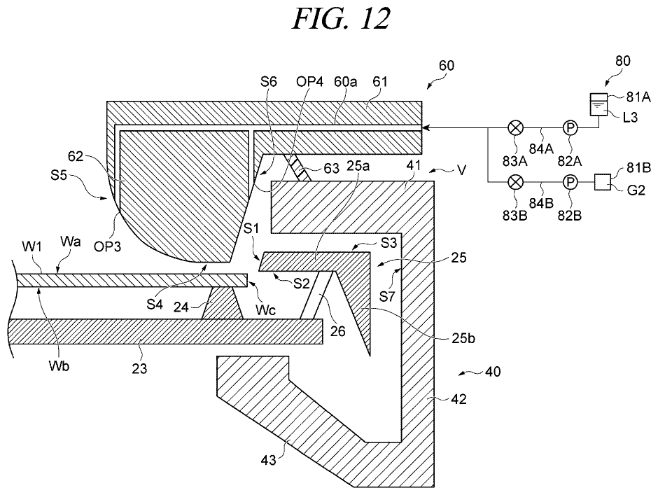

(2) As shown in FIG. 12, a flow path 60 a may be formed inside the rectifier 60. In the example of FIG. 12, the supply 80 is configured to supply the cleaning liquid L3 and the inert gas G2 to the circumferential surface of the rectifying protrusion 62 (e.g., the bottom surface S4, the inner peripheral surface S5, and the outer peripheral surface S6) through the flow path 60a formed in the rectifier 60.

The flow path 60a branches into multiple branch paths at an intermediate portion. Some of the branch paths of the flow path 60a are respectively connected to discharge openings OP3 formed on the inner peripheral surface S5 of the rectifying protrusion 62. The others of the branch paths of the flow path 60a are respectively connected to discharge openings OP4 formed in the outer peripheral surface S6 of the rectifying protrusion 62.

The discharge openings OP3 and OP4 are opened downwards. That is, the cleaning liquid L3 and the inert gas G2 discharged from the discharge openings OP3 and OP4 after passing through the flow path 60a flow along the circumferential surface of the rectifying protrusion 62 (e.g., the bottom surface S4, the inner peripheral surface S5, and the outer peripheral surface S6). The discharge openings OP3 may be arranged at an approximately equal interval therebetween so as to form a circle as a whole when viewed from above. The multiple discharge openings OP4 may be arranged at an approximately equal interval therebetween so as to form a circle as a whole when viewed from above.

According to the example of FIG. 12, since the cleaning liquid L3 is supplied from the multiple discharge openings OP3 and OP4, it is possible to clean the wide range of the circumferential surface (e.g., the bottom surface S4, the inner peripheral surface S5, and the outer peripheral surface S6) of the rectifying protrusion 62. Further, the rectifying protrusion 62 may be provided with the multiple discharge openings OP3 in its inner peripheral surface S5, the multiple discharge openings OP4 in its outer peripheral surface S6, or both the multiple discharge openings OP3 and the multiple discharge openings OP4 in each of the inner peripheral surface S5 and the outer peripheral surface S6.

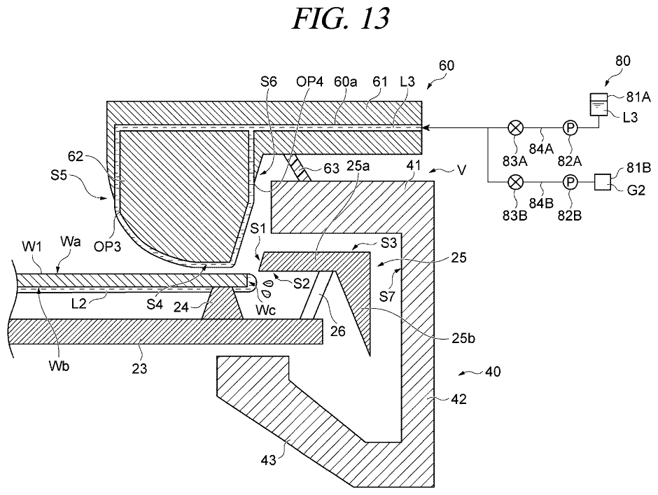

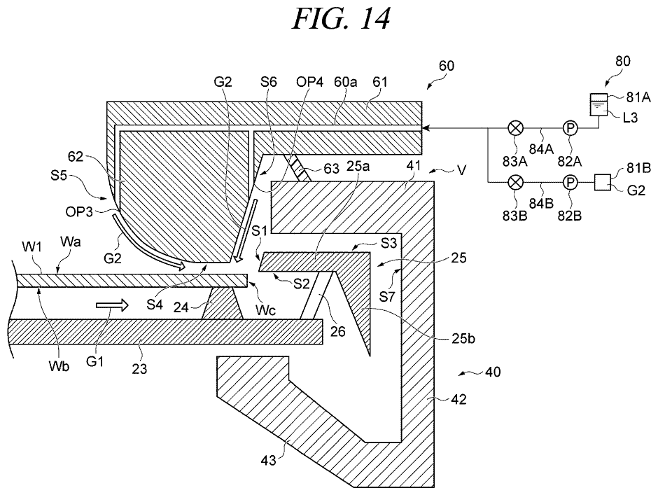

In the example of FIG. 12, the circumferential surface of the rectifying protrusion 62 may be cleaned, the same as in the example of FIG. 11. For instance, as illustrated in FIG. 13, the controller Ctr first controls the supplies 50 and 80 to supply the cleaning liquid L3 to the circumferential surface of the rectifying protrusion 62 through the flow path 60a and the multiple discharge openings OP3 and OP4 while supplying the cleaning liquid L2 through the shaft member 31 toward the rear surface Wb of the cleaning substrate W1 being rotated. Then, as shown in FIG. 14, the controller Ctr controls the supplies 50 and 80 to supply the inert gas G2 to the circumferential surface of the rectifying protrusion 62 through the flow path 60a and the multiple discharge openings OP3 and OP4 while supplying the inert gas G1 through the shaft member 31 toward the rear surface Wb of the cleaning substrate W1 being rotated. As a result, the circumferential surface of the rectifying protrusion 62 is dried by the inert gas G2. This makes it possible to maintain the circumferential surface of the rectifying protrusion 62 clean.

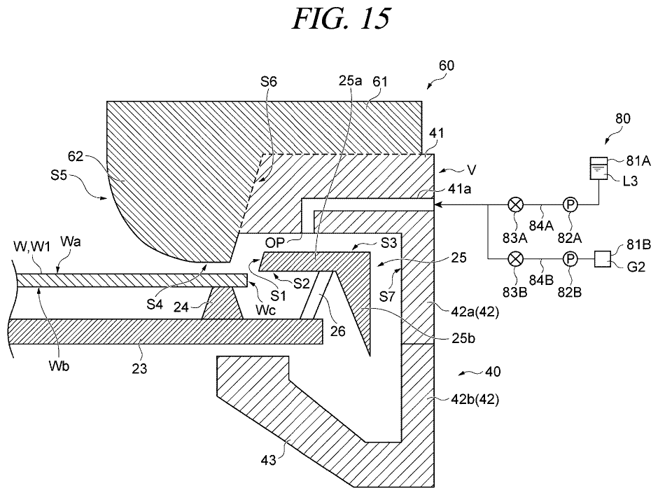

(3) As illustrated in FIG. 15, the cup member 40 and the rectifier 60 may be physically integrated as a single structure. In this case, the sidewall portion 42 may be vertically divided into an upper portion 42a and a lower portion 42b, for example. The elevating device 70 may be configured to move the rectifier 60, the upper wall portion 41, and the upper portion 42a up and down based on an instruction from the controller Ctr.

### Other Examples

### Example 1

An example of a substrate processing apparatus includes a support supporting a substrate; an annular member surrounding the support from an outside thereof; a cover member disposed around the annular member, the cover member having an annular shape; a rotator rotating the support; a first supply supplying a processing liquid toward a rear surface of the substrate supported by the support; and a second supply. The cover member includes a rectifying protrusion, extending in a vertical direction to face a periphery of the substrate supported by the support, positioned at an inner side than the annular member when viewed from the vertical direction; a horizontal portion extending in a horizontal direction to be positioned above the annular member; and a sidewall portion extending in the vertical direction to surround an outer peripheral surface of the annular member. The second supply supplies a cleaning liquid to the rectifying protrusion or the annular member. In this case, the cleaning liquid is supplied to the rectifying protrusion or the annular member. When the cleaning liquid is supplied to the rectifying protrusion, a circumferential surface of the rectifying protrusion is cleaned. When the cleaning liquid is supplied to the annular member, the cleaning liquid that has reached the annular member scatters toward the circumferential surface of the rectifying protrusion, so that the circumferential surface of the rectifying protrusion is cleaned together with the annular member. Therefore, even if a foreign substance (e.g., particles, chemical liquid residue, etc.) adheres to the circumferential surface of the rectifying protrusion, the foreign substance is washed away by the cleaning liquid. This makes it less likely that the foreign substance falls from the circumferential surface of the rectifying protrusion onto the substrate. As a result, adhesion of the foreign substance to a top surface of a periphery of the substrate can be suppressed. Furthermore, as the circumferential surface of the rectifying protrusion is cleaned by the cleaning liquid supplied from the second supply, it is not needed to disassemble the substrate processing apparatus to clean the rectifying protrusion. Therefore, a maintenance work for the substrate processing apparatus can be simplified.

### Example 2

In the apparatus of Example 1, the horizontal portion includes multiple discharge openings and the second supply supplies the cleaning liquid toward at least one of a top surface of the annular member, an outer peripheral surface of the rectifying protrusion or an inner peripheral surface of the sidewall portion from the multiple discharge openings provided in the horizontal portion. In this case, since the cleaning liquid is supplied from the multiple discharge openings, it is possible to clean a wide range of at least one of the annular member, the rectifying protrusion, or the sidewall portion.

### Example 3

In the apparatus of Example 2, the rotator rotates the support and the annular member. In this case, due to the rotation of the annular member, the cleaning liquid supplied to the annular member scatters around vigorously. This makes it possible to more effectively clean the wide range of at least one of the annular member, the rectifying protrusion, or the sidewall portion.

### Example 4

The apparatus of Example 3 further includes controller circuitry configured to execute a first processing of controlling the rotator and the second supply to supply the cleaning liquid to the top surface of the annular member from the multiple discharge openings, while rotating the support and the annular member at a first rotational speed; and a second processing of controlling the rotator and the second supply to supply the cleaning liquid to the top surface of the annular member from the multiple discharge openings, while rotating the support and the annular member at a second rotational speed that is lower than the first rotational speed. In this case, in the first processing, since the annular member is rotated at the relatively high rotational speed (first rotational speed), the cleaning liquid supplied to the annular member scatters vigorously outwards in a radial direction. Accordingly, the cleaning liquid flows primarily toward the inner peripheral surface of the sidewall portion located at an outer side than the annular member in the radial direction. Therefore, the inner peripheral surface of the sidewall portion is mainly cleaned. Meanwhile, in the second processing, the annular member is rotated at the relatively low rotational speed (second rotational speed), causing the cleaning liquid supplied to the annular member to scatter vigorously inwards in the radial direction. Accordingly, the cleaning liquid flows primarily toward the outer peripheral surface of the rectifying protrusion, which is located at the inner side than the annular member in the radial direction. Therefore, the outer peripheral surface of the rectifying protrusion is mainly cleaned. In this way, according to Example 4, by controlling the rotational speed of the annular member, it is possible to more effectively clean the inner peripheral surface of the sidewall portion and the outer peripheral surface of the rectifying protrusion.

### Example 5

In the apparatus of Example 4, the controller circuitry is configured to execute the first processing and the second processing in a state where a cleaning substrate having a shape corresponding to that of the substrate is supported by the support. In this case, the substrate is not consumed when cleaning the rectifying protrusion. Therefore, the cleaning of the rectifying protrusion can be carried out at low cost.

### Example 6

In the apparatus of Example 1, the rectifying protrusion includes multiple discharge openings and the second supply supplies the cleaning liquid to at least one of an outer peripheral surface or an inner peripheral surface of the rectifying protrusion from the multiple discharge openings provided in the rectifying protrusion. In this case, since the cleaning liquid is supplied from the multiple discharge openings, it is possible to clean a wide range of at least one of the outer peripheral surface or an inner peripheral surface of the rectifying protrusion.

### Example 7

In the apparatus of any one of Examples 1 to 6, the rectifying protrusion, the horizontal portion, and the sidewall portion are physically separated from each other. In this case, the rectifying protrusion can be separated from the horizontal portion and the sidewall portion, allowing the substrate to be easily placed on the support.

### Example 8

The apparatus of Example 7 further includes an elevating device including a rod and a slider, the elevating device moving the rectifying protrusion up and down between a raised position where the substrate is carried to/from the support and a processing position near the periphery of the substrate where the substrate is processed. In this case, the rectifying protrusion is moved up and down by the elevating device, making it possible to automatically perform a carry-in/carry-out of the substrate and a processing of the substrate depending on the position of the rectifying protrusion.

### Example 9

In the apparatus of Example 8, the cover member further includes an annular seal member hermetically sealing a gap between the rectifying protrusion and the horizontal portion when the rectifying protrusion is located at the processing position. In this case, when the rectifying protrusion is located at the processing position, the gap between the rectifying protrusion and the horizontal portion is hermetically sealed by the seal member. As a result, an inflow of a gas from the outside into an inner space of the cover member through the gap is suppressed, and likewise, an outflow of a gas from the inner space to the outside through the gap is also suppressed. Therefore, the inner space can be easily maintained clean, so that the adhesion of a foreign substance to the top surface of the periphery of the substrate processed in the inner space may be further suppressed.

### Example 10

In the apparatus of any one of Examples 1 to 9, the cleaning liquid is a rinse liquid or a chemical liquid for cleaning.

### Example 11

The apparatus of any one of Examples 1 to 9 further includes a third supply supplying an inert gas to at least one of the rectifying protrusion or the annular member. In this case, at least one of the rectifying protrusion or the annular member is dried by the inert gas. Therefore, the cleaned rectifying protrusion can be maintained clean.

### Example 12

The apparatus of Example 11 further includes controller circuitry configured to execute a third processing of controlling the second supply to supply the cleaning liquid to at least one of the rectifying protrusion or the annular member; and a fourth processing of controlling the third supply to supply the inert gas to at least one of the rectifying protrusion or the annular member after the third processing. In this case, the same effect as in Example 11 can be achieved.

### Example 13

In the apparatus of Example 12, the controller circuitry is configured to execute the third processing and the fourth processing in a state where a cleaning substrate having a shape corresponding to that of the substrate is supported by the support. In this case, the same effect as in Example 5 can be obtained.

### Example 14

A substrate cleaning apparatus, comprises a housing, a rotator including a rotation shaft, a driver, a support plate, a plurality of support pins and an annular member, the plurality of support pins being for supporting a substrate, an elevating device including a shaft member, a driver and multiple support pins, the driving mechanism moving the shaft member along a vertical axis, a cup member, a first supply including a first pump and the first supply supplying a processing liquid toward a rear surface of the substrate supported by the plurality of support pins, a rectifier, a second supply including a second pump and supplying cleaning liquid to the annular member, a blower; and controller circuitry configured to control the elevating device, the first pump, the second pump and the blower to clean the substrate.

### Example 15

In the apparatus of Example 14, the second supply supplies the cleaning liquid and the inert gas to a top surface of the annular member through a flow path of the cup member.

### Example 16

In the apparatus of Example 15, the cup member includes an upper wall portion extending in a horizontal direction and positioned above the annular member; a sidewall portion extending in a vertical direction and surrounding an outer peripheral surface of the annular member; and a bottom wall portion.

### Example 17

In the apparatus of Example 16, the upper wall portion includes the flow path that branches into multiple discharge openings at an intermediate portion of the upper wall portion.

### Example 18

In the apparatus of Example 17, the controller circuitry executes a first processing of controlling the rotator and the second supply to supply the cleaning liquid to the top surface of the annular member from the multiple discharge openings, while rotating the support and the annular member at a first rotational speed.

### Example 19

In the apparatus of Example 17, the controller circuitry further executes a second processing of controlling the rotator and the second supply to supply the cleaning liquid to the top surface of the annular member from the multiple discharge openings, while rotating the support and the annular member at a second rotational speed that is lower than the first rotational speed.

### Example 20

A cleaning method, includes providing a substrate cleaning apparatus, comprising: a housing; a rotator including a rotation shaft, a driver, a support plate, a plurality of support pins and an annular member; an elevating device including a shaft member, a driver and multiple support pins; a cup member; a second elevating device being a linear cylinder; a first supply including a first pump; a rectifier including a rectifying protrusion overlapping a periphery of the multiple support pins; a second supply including a second pump; a blower; and controller circuitry; providing a substrate on the multiple support pins; by the controller circuitry: controlling the driver of the rotator to rotate the rotation shaft at a preset rotational speed; controlling the blower to create a downward flow towards a top surface of the substrate through an inner surface of the rectifier; and controlling the first supply to supply cleaning liquids through the shaft member toward a rear surface of the substrate being rotated, the downward flow flows along an inner peripheral surface of the rectifying protrusion and into a gap between a bottom surface of the rectifying protrusion and the top surface of the substrate and then into first and second branch flow to block droplets from reaching a center of the substrate.

According to the exemplary embodiment, it is possible to suppress the foreign substance from adhering to the top surface of the periphery of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

We claim

1. A substrate processing apparatus, comprising:
a support supporting a substrate;
an annular member surrounding the support from an outside thereof;
a cover member disposed around the annular member, the cover member having an annular shape;
a rotator rotating the support;
a first supply supplying a processing liquid toward a rear surface of the substrate supported by the support; and
a second supply,
wherein the cover member comprises:
a rectifying protrusion, extending in a vertical direction to face a periphery of the substrate supported by the support, positioned at an inner side than the annular member when viewed from the vertical direction;
a horizontal portion extending in a horizontal direction and positioned above the annular member; and
a sidewall portion extending in the vertical direction surrounding an outer peripheral surface of the annular member, and
the second supply to supply a cleaning liquid to the rectifying protrusion or the annular member.

2. The substrate processing apparatus of claim 1,
wherein the horizontal portion includes multiple discharge openings, and
the second supply is to supply the cleaning liquid toward at least one of a top surface of the annular member, an outer peripheral surface of the rectifying protrusion or an inner peripheral surface of the sidewall portion from the multiple discharge openings provided in the horizontal portion.

3. The substrate processing apparatus of claim 2,
wherein the rotator rotates the support and the annular member.

4. The substrate processing apparatus of claim 3, further comprising:
controller circuitry configured to execute:
a first processing of controlling the rotator and the second supply to supply the cleaning liquid to the top surface of the annular member from the multiple discharge openings, while rotating the support and the annular member at a first rotational speed; and
a second processing of controlling the rotator and the second supply to supply the cleaning liquid to the top surface of the annular member from the multiple discharge openings, while rotating the support and the annular member at a second rotational speed that is lower than the first rotational speed.

5. The substrate processing apparatus of claim 4,
wherein the controller circuitry is configured to execute the first processing and the second processing in a state where a cleaning substrate having a shape corresponding to that of the substrate is supported by the support.

6. The substrate processing apparatus of claim 1,
wherein the rectifying protrusion includes multiple discharge openings, and
the second supply supplies the cleaning liquid to at least one of an outer peripheral surface or an inner peripheral surface of the rectifying protrusion from the multiple discharge openings provided in the rectifying protrusion.

7. The substrate processing apparatus of claim 1,
wherein the rectifying protrusion, the horizontal portion, and the sidewall portion are physically separated from each other.

8. The substrate processing apparatus of claim 7, further comprising:
an elevating device including a rod and a slider, the elevating device moving the rectifying protrusion up and down between a raised position where the substrate is carried to/from the support and a processing position near the periphery of the substrate where the substrate is processed.

9. The substrate processing apparatus of claim 8,
wherein the cover member further comprises an annular seal member hermetically sealing a gap between the rectifying protrusion and the horizontal portion when the rectifying protrusion is located at the processing position.

10. The substrate processing apparatus of claim 1,
wherein the cleaning liquid is a rinse liquid or a chemical liquid for cleaning.

11. The substrate processing apparatus of claim 1, further comprising:
a third supply supplying an inert gas to at least one of the rectifying protrusion or the annular member.

12. The substrate processing apparatus of claim 11, further comprising:
controller circuitry configured to execute: a third processing of controlling the second supply to supply the cleaning liquid to at least one of the rectifying protrusion or the annular member; and
a fourth processing of controlling the third supply to supply the inert gas to at least one of the rectifying protrusion or the annular member after the third processing.

13. The substrate processing apparatus of claim 12,
wherein the controller circuitry is configured to execute the third processing and the fourth processing in a state where a cleaning substrate having a shape corresponding to that of the substrate is supported by the support.

14. A substrate cleaning apparatus, comprising:
a housing;
a rotator including a rotation shaft, a driver, a support plate, a plurality of support pins and an annular member, the plurality of support pins being for supporting a substrate;
an elevating device including a shaft member, a driver and multiple support pins, the driving mechanism moving the shaft member along a vertical axis;
a cup member;
a first supply including a first pump and the first supply supplying a processing liquid toward a rear surface of the substrate supported by the plurality of support pins;
a rectifier;
a second supply including a second pump and supplying cleaning liquid to the annular member;
a blower; and
controller circuitry configured to control the elevating device, the first pump, the second pump and the blower to clean the substrate.

15. The substrate cleaning apparatus of claim 14, wherein the second supply supplies the cleaning liquid and the inert gas to a top surface of the annular member through a flow path of the cup member.

16. The substrate cleaning apparatus of claim 15, wherein the cup member includes:
an upper wall portion extending in a horizontal direction and positioned above the annular member;
a sidewall portion extending in a vertical direction and surrounding an outer peripheral surface of the annular member; and
a bottom wall portion.

17. The substrate cleaning apparatus of claim 16, wherein the upper wall portion includes the flow path that branches into multiple discharge openings at an intermediate portion of the upper wall portion.

18. The substrate cleaning apparatus of claim 17, wherein the controller circuitry executes:
a first processing of controlling the rotator and the second supply to supply the cleaning liquid to the top surface of the annular member from the multiple discharge openings, while rotating the support and the annular member at a first rotational speed.

19. The substrate cleaning apparatus of claim 17, wherein the controller circuitry further executes:
a second processing of controlling the rotator and the second supply to supply the cleaning liquid to the top surface of the annular member from the multiple discharge openings, while rotating the support and the annular member at a second rotational speed that is lower than the first rotational speed.

20. A cleaning method, comprising:
providing a substrate cleaning apparatus, comprising:
a housing;
a rotator including a rotation shaft, a driver, a support plate, a plurality of support pins and an annular member;
an elevating device including a shaft member, a driver and multiple support pins;
a cup member;
a second elevating device being a linear cylinder;
a first supply including a first pump;
a rectifier including a rectifying protrusion overlapping a periphery of the multiple support pins;
a second supply including a second pump;
a blower; and
controller circuitry;
providing a substrate on the multiple support pins;
by the controller circuitry:
controlling the driver of the rotator to rotate the rotation shaft at a preset rotational speed;
controlling the blower to create a downward flow towards a top surface of the substrate through an inner surface of the rectifier; and
controlling the first supply to supply cleaning liquids through the shaft member toward a rear surface of the substrate being rotated, the downward flow flows along an inner peripheral surface of the rectifying protrusion and into a gap between a bottom surface of the rectifying protrusion and the top surface of the substrate and then into first and second branch flow to block droplets from reaching a center of the substrate.
